(19) United States
(12) Patent Application Publication
(10) Pub. No.: US 2008/0144243 A1
(43) Pub. Date: Jun. 19, 2008

(54) Method and circuit for low-power detection of solder-joint network failures in digital electronic packages

(75) Inventors: Giorgio Mariani, Phoenix, AZ (US); James P. Hofmeister, Tucson, AZ (US); Justin B. Judkins, Tucson, AZ (US)

Correspondence Address: ERIC A. GIFFORD, 11770 E. CALLE DEL VALLE, TUCSON, AZ, 85749, US

(73) Assignee: Ridgetop Group, Inc.

(21) Appl. No.: 11/803,562

(22) Filed: May 14, 2007

Related U.S. Application Data
(60) Provisional application No. 60/875,584, filed on Dec. 19, 2006.
(60) Provisional application No. 60/879,518, filed on Jan. 10, 2007.

(51) Int. Cl. H02H 9/04; G01R 31/26

(52) U.S. Cl. 361/56; 324/765

(57) ABSTRACT

A low power circuit and method for detects in-situ failures or precursors to failures in solder-joint networks on actual operational devices and packages in the field. An amplifying detector such as provided by a common-gate transistor sources current to the network to generate a signal voltage and a reference voltage that is sensitive to the low voltage applied to the other side of the network. Generation of this self-adjusting reference voltage makes the detection circuit insensitive to the network low-voltage. Additional power savings and performance gains can be provided with the addition of a differential amplifier to set a fixed bias point and a level shifter to cancel noise. The detected failure or precursor of a selected monitor solder-joint network(s) is an indicator of the integrity of other operational solder-joint networks in the package, on the PWB or between PWBs.

### CROSS-REFERENCE TO RELATED APPLICATIONS

This application claims benefit of priority under 35 U.S.C. 119(e) to U.S. Provisional Application Nos. 60/875,584 entitled “Method and circuit for the detection of solder-joint failures in digital electronic packages in a manner which is insensitive to the steady-state voltage level to the monitored solder-joint network and which suppresses both random and common-mode noise” filed on Dec. 19, 2006 and 60/879,518 entitled “Method and circuit for low-power detection of solder-joint failures in digital electronic packages in a manner which is insensitive to the steady-stage voltage level of the monitored solder joint networks and which suppresses noise” filed on Jan. 10, 2007, the entire contents of which are incorporated by reference.

### GOVERNMENTAL RIGHTS

This invention was made with Government support under Contract N68335-06-C-0346 awarded by Naval Air Warfare Center AD (LKE). The Government has certain rights in this invention.

### BACKGROUND OF THE INVENTION

1. Field of the Invention

This invention relates to a method and circuit for low-power detection of failures in solder-joint networks.

2. Description of the Related Art

Solder-joint connections are a major reliability problem in electronic packaging. In general, a solder-joint network includes a combination of active circuit components, wires, connection points, one or more pads, one or more solder balls, and power and ground connections, any or all of which are located both on and off an integrated circuit die (chip) or printed wire board (PWB).

A solder-joint network may be as simple as a single solder-joint connection on a printed wire board (PWB). The network may be defined by the connections between digital electron packages such as FPGAs or Microcontrollers on different PWBs. In particular, the connections provided by connectors and cable harnesses, are prone to connection failure because of a fracture or high-resistance contact such as that between a connector and a cable-harness pin. Of particular interest are networks defined between mechanical connections that lie inside the digital logic on the die, through the multiple mechanical connections and internal solder-joint connections between the die and digital electronic package and through the external solder-joint connections to circuitry on the PWB. Modern Ball Grid Array (BGA) packages have more than one thousand pins and the number of pins on these packages increases as the density of integrated circuit chips increases. The increased number of pins on the packages is necessary to support the evolving complexity of circuits; however, one of the drawbacks of the increase is reduced reliability.

As shown in FIG. 1, an exemplary FPGA 10 comprises at least one flip-chip 12 consisting of a die mount 18 and die 16 mounted inside a cavity 14 of a BGA package 22. The FPGA includes an array of operational I/O ports each connected to an I/O pad on the die. Flip-chip 12 is placed inside BGA package 22 so that solder balls 20 (also called solder bumps) contact respective I/O pads on the die 16. Each solder ball 20 is attached to a via 36 at the inside surface at the bottom of package 22 to form an internal solder-joint connection. The other end of via 36 is attached to an outside ball limiting metallurgy (BLM) 24, which is attached to a primary solder ball 26 to constitute an I/O pin and complete the FPGA 10. The FPGA is placed so that primary BGA solder balls 26 contact solder paste on metal LANDs 28 on a PWB 30. The assembled PWB is heated and the solder balls 26 and solder paste melt and reflow to attach to metal LANDs 28 to form an external solder-joint connection. The PWB is configured so that the metal LANDs are connected by vias 38 and wiring 32 to one or more nodes 34 for external circuitry on the PWB. A connector and harness may be provided to connect the FPGA to another package on a different PWB.

FIG. 2 shows a simplified representation of an operational I/O port 40 in the FPGA. I/O port 40 includes read input logic 42 connected to an input buffer 44 comprised of transistor circuitry controlled by wiring 46. I/O port 40 also includes write logic 48 which is connected to write output buffer 50 that is controlled by wiring 52. The read input buffer 44 and write output buffer 50 are connected to an I/O pad 54 by wiring 56 and connections 58. I/O port 40 also includes electro-static discharge (ESD) circuitry that can be complex or simple. A simple ESD circuit consists of a power source 60, protection diodes 62 and 64 and common reference or ground 66.

As shown in FIG. 3, the integrity of external solder joints can be evaluated using “2-wire” or “4-wire” techniques. Wire segments 70 connect vias 72 inside the BGA package 74 and PWB wiring 76 connects pads 78 on the PWB 79 to primary solder balls 80 attached to ball-limiting metallurgy (BLM) 82 from the primary BGA in a “daisy chain.” A meter 84 directly measures the resistance of the daisy chain at the same time by applying a voltage and measuring a current or vice-versa. The meter typically applies well-regulated, low noise voltages or currents. Alternately, the wire segments and PWB can be configured to measure the resistance between two solder balls 80 at a time, so increases in resistance due to fracturing can be monitored. Defects are judged by the degree of change in the connection resistance of the daisy chain.

These “2-wire” and or “4-wire” techniques for direct measurement of solder-joint resistance have a number of limitations. The BGA package is typically a “blank” or “dummy” package, e.g. the pins do not include the operational logic gates, buffers and internal solder-joint connections that make up the operational I/O ports of an FPGA. Therefore, the tests are limited to the external solder-joint connections and cannot test the entire solder-joint network for a digital electronic package. The manufacturer of the BGA package can evaluate the reliability of the blank package but the end user has no capability to evaluate the reliability of the finished FPGA or Microcontroller package. Furthermore, these tests are performed in the lab on non-operational devices to gather information about the packages. These tests provide no ability to actually monitor the health of a solder-joint network of an operational package in the field.

U.S. Pat. No. 6,452,502 B1 issued Sep. 17, 2002 to Dishongh et al, places a small set of specially-wired pins on a PWB and another small set of non-operational and internally connected pins on an operational package. The pins on the PWB mimic the wiring 76 and pads 78 of the test circuit in FIG. 2. The non-operational pins on the package mimic the wiring 70, vias 72, BLM 82 and solder balls 80 of the test circuit in FIG. 2. Together they form a daisy chain in an operational and fielded device. Dishongh uses a latch-up circuit in series with the completely-wired daisy chain to detect a first open failure anywhere in the multitude of daisy-chained dummy I/O pins and their interconnecting, chained wiring inside the package and outside on the PWB. Once an open occurs sufficient to cause a voltage change of one-half of the power supply or larger, the latch-up circuit is turned on and remains turned on even after the open condition no longer exists. Although Dishongh provides some capability to monitor solder-joint connections in operational and fielded devices, his approach is again limited to the external solder-joint connections of only the BGA package.

### SUMMARY OF THE INVENTION

The following is a summary of the invention in order to provide a basic understanding of some aspects of the invention. This summary is not intended to identify key or critical elements of the invention or to delineate the scope of the invention. Its sole purpose is to present some concepts of the invention in a simplified form as a prelude to the more detailed description and the defining claims that are presented later.

The present invention provides a low power circuit and method for reliable detection of in-situ failures or precursors to failures in operational solder-joint networks on actual operational devices and packages in the field. The circuit can monitor the entire solder-joint network for a digital electronic package including internal and external solder-joint connections. The detected failure or precursor of a selected monitor solder-joint network(s) is an indicator of the integrity of other operational solder-joint networks in the package, on the PWB or between PWBs.

This is accomplished by first holding one side of a designated monitor solder-joint network at a low voltage including a steady-state component and noise, suitably by pulling the write logic output buffer on the die low. The steady-state low voltage may be unknown, different output buffers produce different values, may vary with load current and may vary among different monitor networks on the same package or board. The detection circuit is designed to be insensitive to variations and differences in the steady-state low voltage. This design allows the detection circuit to use small currents to detect small resistance changes in the network and to operate at low power.

A fault detection circuit is connected to the other side of the solder-joint network. An amplifying detector sources a small amount of load current through the network to establish a small signal voltage (above a noise threshold) that rides on the low voltage, amplifies and filters the voltage to produce an analog output voltage that includes amplified steady-state, signal (when a fault is present) and noise components and an analog reference voltage that includes only the amplified steady-state component. A comparator includes a differential comparator that compares the analog output voltage to the analog reference voltage to generate an amplified single-ended analog signal that drives an output buffer between logical level 0 and 1 to switch a logic ‘fault’ signal for the monitor solder-joint network that is an indicator of the integrity of the other solder-joint networks. A second output buffer responsive to the reference voltage switches a logic ‘open’ signal for the monitor solder-joint network as another indicator of the integrity of the other solder-joint networks. The fault signal indicates the occurrence of any fault in the network while the open signal indicates the occurrence of a large and sustained fault.

In another embodiment, the amplifying detector includes a common-gate transistor that provides the amplification. The load current flows through the transistor into the solder-joint network. The common-gate transistor produces the analog output voltage at its drain terminal. A filter is connected between the drain and gate terminals to bias the transistor and to produce the reference voltage. This approach eliminates the separate drain current that would be required to power an amplifier that was not connected between the current source and network, which lowers total current and power consumption.

In another embodiment, the comparator includes a differential amplifier stage that differentially amplifies the output and reference voltages so that the amplified signal and amplified noise ride on a fixed steady-state voltage that is insensitive to the low voltage input at the solder-joint network. The output of this stage is a differential signal in which a positive signal rides on the fixed steady-state voltage and a negative signal rides on the fixed steady-state voltage. These voltages are then input to the comparator. The use of the differential amplifier establishes a reliable steady-state voltage or bias, which is insensitive to the low voltage on the network, into the differential comparator. This bias point is selected to provide a desired non-linear amplification of the signal voltage as compared to noise to improve SNR.

In another embodiment, the comparator also includes a level-shift stage that level shifts one of the outputs of the differential amplifier stage by, for example, the designed for noise threshold. As a result, the differential comparator cancels noise thereby further improving SNR. The advantage is that the load current can be made smaller and achieve the same or better performance. Alternately, the level-shift stage may be positioned in front of the differential amplifier.

These and other features and advantages of the invention will be apparent to those skilled in the art from the following detailed description of preferred embodiments, taken together with the accompanying drawings, in which:

### BRIEF DESCRIPTION OF THE DRAWINGS

FIG. 1, as described above, is a diagram illustrating an exemplary FPGA which contains solder-joint networks in a typical digital electronic package;

FIG. 2, as described above, is a simplified representation of an operational I/O port in the FPGA;

FIG. 3, as described above, is a diagram of a conventional direct resistance measurement to evaluate the integrity of the solder joints formed between the primary BGA of a blank BGA package and the PWB;

FIG. 4 is a block diagram of a solder-joint fault detector connected to a monitor solder-joint network in accordance with the present invention;

FIG. 5 is a schematic diagram of an amplifying detector that sources current to the monitor solder-joint network to produce output and reference voltages;

FIGS. 6a through 6d are plots of the solder-joint, drain, gate, fault and open voltage signals for different types of network faults;

FIG. 7 is a block diagram of an alternate embodiment of the comparator including differential amplifier and level shifter stages;

FIG. 8 is a schematic diagram of a differential amplifier;

FIG. 9 is a schematic diagram of a level shifter;

FIG. 10 is a schematic diagram of a differential comparator that produces a single-ended analog voltage output that is insensitive to the reference voltage;

FIGS. 11-16 are plots of voltage signals at the output of the solder-joint network, amplifying detector, differential amplifier, level shifter, differential comparator and output buffer, respectively; and

FIG. 17 is a plot of the fault and open logic signals output by the detector.

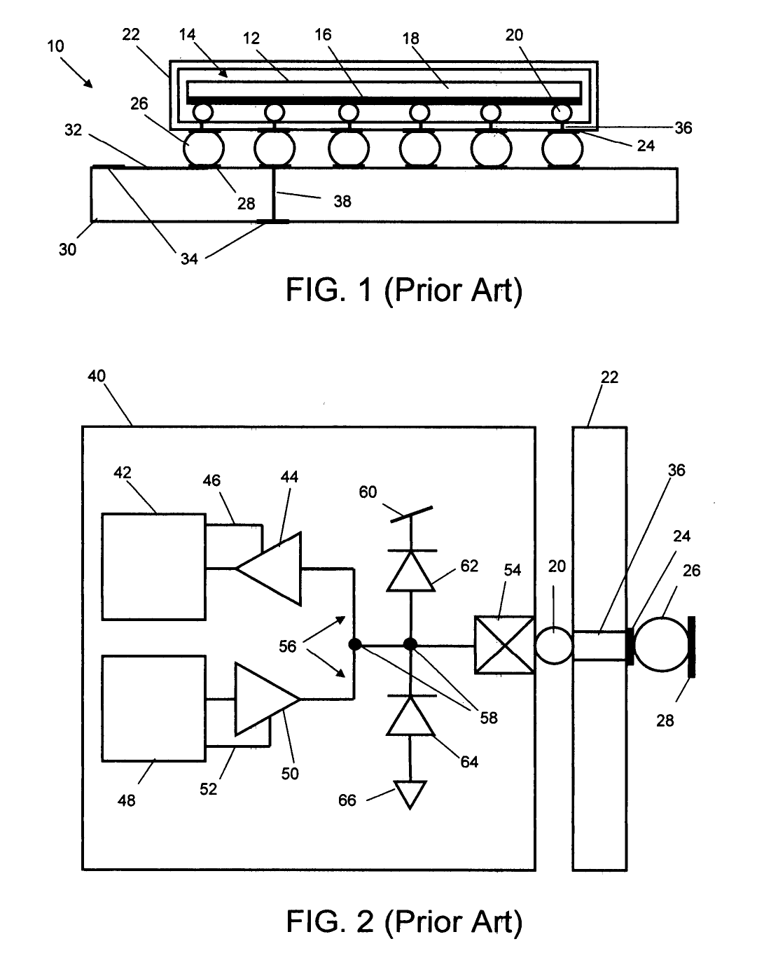

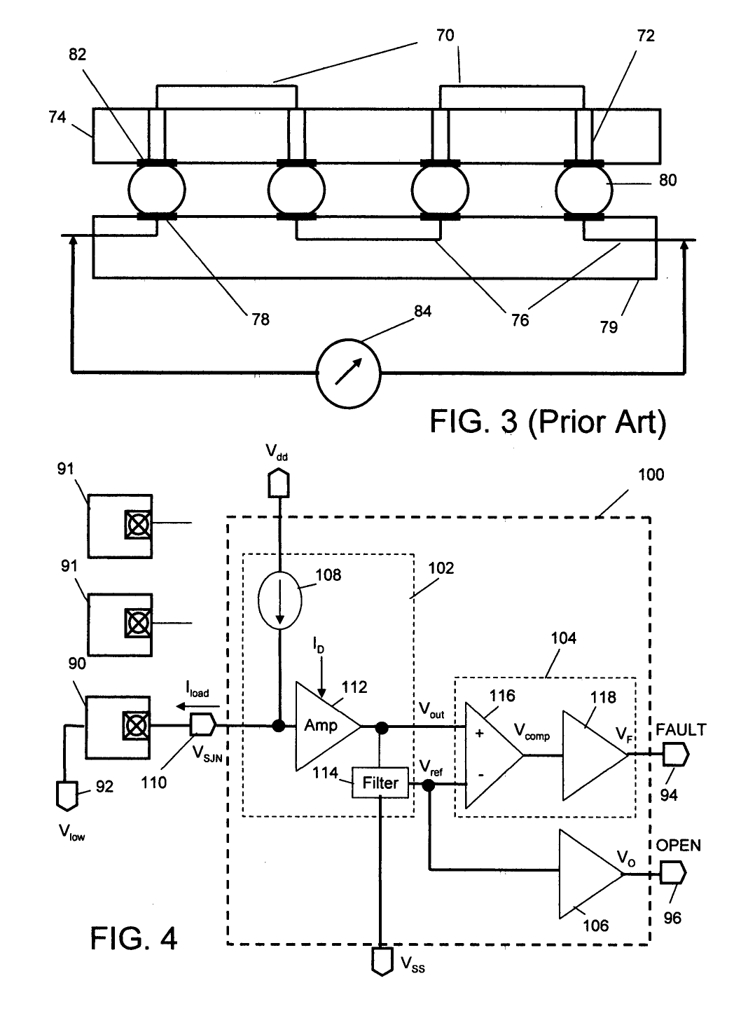

### DETAILED DESCRIPTION OF THE INVENTION

The present invention provides a low power circuit and method for detecting in-situ failures or precursors to failures in solder-joint networks on actual operational devices and packages in the field. The circuit can detect failures in a solder-joint network defined from the logic inside the die of an FPGA or microcontroller, through the internal and external solder-joint connections to circuit connections on a PWB in actual operational devices and packages in the field. The detected failure or precursor of a selected monitor solder-joint network(s) is an indicator of the integrity of other operational solder-joint networks in the package, on the PWB or between PWBs.

This is accomplished by first holding one side of a designated monitor solder-joint network at a low voltage including a steady-state component and noise, suitably by pulling the write logic output buffer on the die low. There is a large variation between the steady-state low-voltage (voltage-low) of transistor output buffers, such as those used in FPGA I/O ports. An output buffer of device A at a load current of 2.5 mA might be 320 mV and the output buffer of device B at the same load current might be 100 mV. Further, the voltage-low of pulled-down output buffers is typically directly proportional to the load current. For example, if the load current of the output buffer of device A is reduced from 2.5 mA to 100 μA, a 25-to-1 reduction, the voltage-low is similarly reduced, from 320 mV to 12.8 mV. For device B, voltage-low is reduced from 100 mV to 4 mV (25:1 reduction).

The differences in voltage-low (320 mV compared to 2 mV) must be considered in the design of any detector attached to a solder-joint network, in which the low voltage lies within a known range but is undetermined within that range. One possible solution is to design and use a multiplicity of detectors, each an embodiment tuned to a specific set of devices at specific operating points. A second possible solution is to provide a detector that is “tuned” for a specific device and operating point. A third possible solution, as described in recently issued U.S. Pat. No. 7,196,294, is to use a fixed reference voltage such that the detector will not turn on until the monitored voltage is equal to or greater than the reference voltage. The fixed reference voltage must be at least the maximum voltage-low, including noise, of a set of electronic devices and their output buffers for the load current imposed by the detector. This is a simple and effective circuit for detecting failures in solder-joint networks. However, the load current required to detect small changes in resistance of the network is relatively high to guarantee that the signal voltage due to the change in resistance exceeds the maximum voltage-low. The result is the detection circuit is relatively high power, e.g. over 40 mw for 8 monitored pins.

The present invention provides an in-situ detection circuit and method for a fielded operational device that is insensitive to the low voltage. Consequently the amount of load current need only be enough to provide adequate headroom over the noise. For example, to achieve the same detection sensitivity the current detection system may require only 100-150 μA, where the U.S. Pat. No. 7,196,294 circuit requires 2.5 mA to ensure detection for the maximum low voltage, at least a 15-to-1 reduction resulting in considerable power savings. The result is the detection circuit is low power. For example, for a TSMC American Semiconductor 0.25 micron process node, simulations of the detection circuit estimate at most 5.2 mw, nominally 4 mw and as low as 2.8 mw for a typical package with 8 monitored pins. Simulations for a TSMC IBM 0.13 micron process node would reduce the power ratings by about one-half. The tradeoff is that the current detection circuit includes additional circuitry.

Referring to FIG. 4, each monitored solder-joint network represented by a symbol 90 is connected to a solder-joint failure detector 100. In the case of a solder-joint network spanning the internal mechanical connections on a die in a digital electronic package such as an FPGA or Microcontroller to external mechanical connections on a PWB, symbol 90 represents at least the write logic output buffer 50, I/O pad 54, wiring 56, internal connections 58, internal solder ball 20, via 36, ball-limiting metallurgy 24, external solder ball 26, and metal LAND 28 shown in FIG. 2. Additional connections may be included in the network inside or outside the package. Symbol 90 may also represent networks on a PWB or between PWB. A solder-joint network 90, when pulled low (V_{low}) on one side 92, has an effective resistance which is about 20 to 300 Ohms depending on the low voltage and the load current through solder-joint network 90. Of that effective resistance only a few milli-Ohms of resistance are attributable to a good solder joint connection.

Faults in the network manifest themselves as increases in resistance. Open failures manifest as a relatively long and large increase in the resistance. The detector switches FAULT and OPEN logic signals at outputs 94 and 96, respectively, as indicators of the integrity of other operational solder-joint networks 91 in the package. The detector is designed for a nominal operating temperature and supply voltage and nominal/maximum power consumption per monitored network. The detector is designed to guarantee a FAULT logic signal will be generated when an increase in resistance greater than a defined minimum amount, e.g. 100 Ohms, occurs. The defined amount can be made arbitrarily small down to about 1 Ohm but at the cost of increased load current, hence power consumption. The detector may generate a FAULT logic signal for smaller increases in resistance, e.g. greater than 20 Ohms. It is important to note that these FAULT signals are not false positives but true indicators of faults in the network albeit small ones. Variations in the network resistance not attributable to faults are very small (<1 Ohm) and do not trigger false positives. The detector is also designed to guarantee an OPEN logic signal will be generated when a combination of the increase in resistance and the duration of the fault produces a voltage greater than a define amount, e.g. ½ V_{dd}, to switch a buffer. For example, the detector may be designed to detect faults greater than 10 kilo-Ohms and 15 microsecond duration.

Solder-joint failure detector 100 includes an amplifying detector 102 that sources a load current I_{load} into the solder-joint network to produce an analog output voltage Vₒᵤₜ and an analog reference voltage V_{ref}, a comparator 104 that compares Vₒᵤₜ to V_{ref} to switch the FAULT logic signal V_{F} at output 94, and an output buffer 106 that is responsive to V_{ref} to switch the OPEN logic signal V_{O} at output 96. The FAULT logic signal indicates the occurrence of any fault in solder-joint network 90 albeit a very short, very small resistance fault or a persistent, large resistance fault. The OPEN logic signal indicates the occurrence of a persistent, large resistance fault. Furthermore, the OPEN logic signal will remain switched on for approximately the duration of the open fault.

Amplifying detector 102 includes a current source 108 that sources a constant load current I_{load} into the other side 110 of the solder-joint network 90, an amplifier 112 that amplifies the voltage V_{SJN} on the network to produce analog output voltage Vₒᵤₜ, and a filter 114 that filters the output voltage to produce analog reference voltage V_{ref}. Filter 114 removes any signal or noise components leaving the amplified steady-state component of V_{low}. Amplifier 112 requires a drain current I_{D} to operate and provide the desired gain. As shown in this functional schematic, I_{load} and I_{D} are separate currents of roughly the same value. Consequently, the total current, hence power consumption is determined by the two currents. As will be described below, in a preferred embodiment the amplifier 112 is a common-gate transistor provided in series with the load current, thus eliminating the need for a separate current and further reducing power consumption.

Because V_{ref} tracks the actual steady-state component of Vₒᵤₜ, which is sensitive to V_{low}, the detection circuit is insensitive to the specific value of V_{low} for a given package, pin or load current. Consequently I_{load} only need be large enough that a fault in the network produces a signal voltage at 110 with an adequate initial noise margin above a designed for noise threshold of V_{low}. To design the circuit, a minimum amount of resistance change for a fault that is guaranteed to be detected must be defined. For example, if the noise threshold is 2.5 mv, a load current of 50 micro amps through a 100 Ohm fault would produce a 5 mv signal providing an initial SNR of 2:1. As discussed above, smaller faults in the network may or may not be detected. To reliably switch comparator 104, the signal needs to be amplified and the SNR improved. Amplifier 112 provides a small signal gain that amplifies the signal and noise and a large signal gain that amplifies the steady-state voltage on the network. The amplifier may, for example, provide a nominal small-signal gain of 30. The amplifier is suitably biased to operate in its non-linear region so that the actual gain of the signal is greater than the gain of noise, thereby improving the SNR to say 3:1 at the output of the amplifier. In the current example, the amplified signal component of Vₒᵤₜ may be 150 mv and the amplified noise component 50 mv. Filter 114 removes both the signal and noise components from Vₒᵤₜ leaving only the amplified steady-state component as V_{ref}.

Comparator 104 includes a differential comparator 116 that differentially amplifies the analog output and reference voltages to produce a single-ended analog voltage V_{comp} that switches an output buffer 118 to produce the FAULT logic signal V_{F} for the monitor solder-joint network as an indicator of the integrity of the other solder-joint networks. The differential comparator 116 provides additional small-signal gain and is preferably biased to further improve the SNR of V_{comp}. The values of the load current and small-signal gains of amplifiers 112 and 116 are designed such that any fault that manifests as an increase in resistance of at least the defined minimum amount, is guaranteed to produce a value of V_{comp} that is sufficiently large to switch output buffer 118 and that in the absence of any fault the designed for noise threshold is not large enough to switch the output buffer. Smaller faults may or may not output a FAULT signal. Buffers typically switch at approximately one-half of their supply voltage V_{dd}. For example, assume the supply voltage V_{dd} to output buffer 118 is 3 volts and the SNR into the buffer is 6:1. If the minimum fault produces a 2.5 V signal, 2.5 V>1.5 V and the FAULT logic signal will switch high indicating the occurrence of a fault. Conversely, if SNR is 6:1 the noise is less than 0.5 V and will not switch the FAULT logic signal and therefore will not produce a false positive. In this example a 50 or 60 Ohm fault may or may not switch the buffer's FAULT logic signal high.

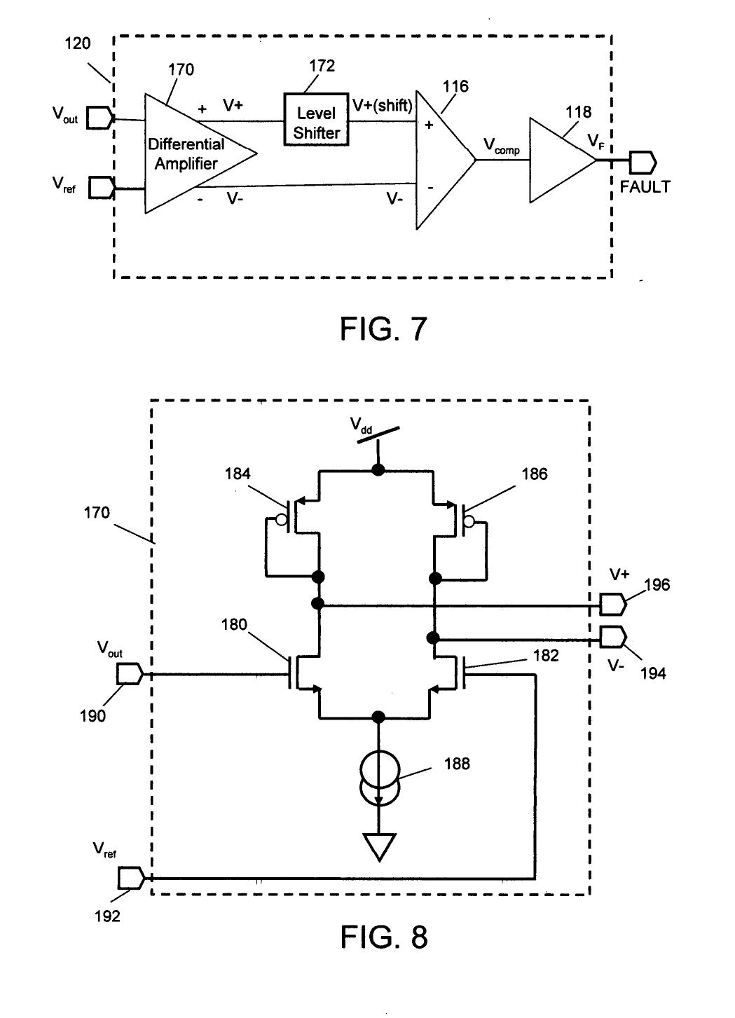

Solder-joint failure detector 100 will be described in additional detail for both a ‘reduced’ comparator circuit 104 of the type shown in FIG. 4 and a ‘full’ comparator circuit 120 of the type shown in FIG. 7. The full circuit provides improved SNR at lower power but requires additional input stage circuitry. In the described embodiments, the high supply voltage V_{dd} shared by the detector and the solder-joint network is a positive voltage and the low supply voltage Vₛₛ is ground reference potential.

The same circuit topology for the detector and principles of operation apply to a complementary form of the detector in which the high supply V_{dd} is held at ground reference potential and the low supply Vₛₛ is a negative voltage. In this configuration, the N-channel inputs are changed to P-channel inputs and vice versa, N-channel active loads (diode-connected transistors) are changed to P-channel active loads and vice versa, N-channel current mirrors are changed to P-channel current mirrors and vice versa, positive DC levels become Negative DC levels, and positive going pulses are changed to negative going pulses and vice versa.

A complementary detector can be used to detect solder joint faults in digital electronic packages such as FPGAs that are powered off—as is typically the case for missiles in transit or in storage. All of the I/O ports of operational FPGAs contain at least one type of Electrostatic Static Discharge (ESD) protection circuit: the Human Body Model (HBM). Most modern FPGAs, especially those manufactured using CMOS process nodes of 130 nm or smaller, include a second ESD protection circuit: the Charge Device Model (CDM). The most common ESD protection circuit for either of both of those employ reverse-biased protection diodes: between ground and the port are one or more diodes with the cathode(s) nearest the port connection; between V_{dd} and the port are one or more diodes with the cathode(s) nearest the VDD connection as shown by diodes 64 and 62 in FIG. 2. So with power off and negative voltage, current will flow from ground through one or more diodes and then out of the port providing a path for negative I_{load} current to flow.

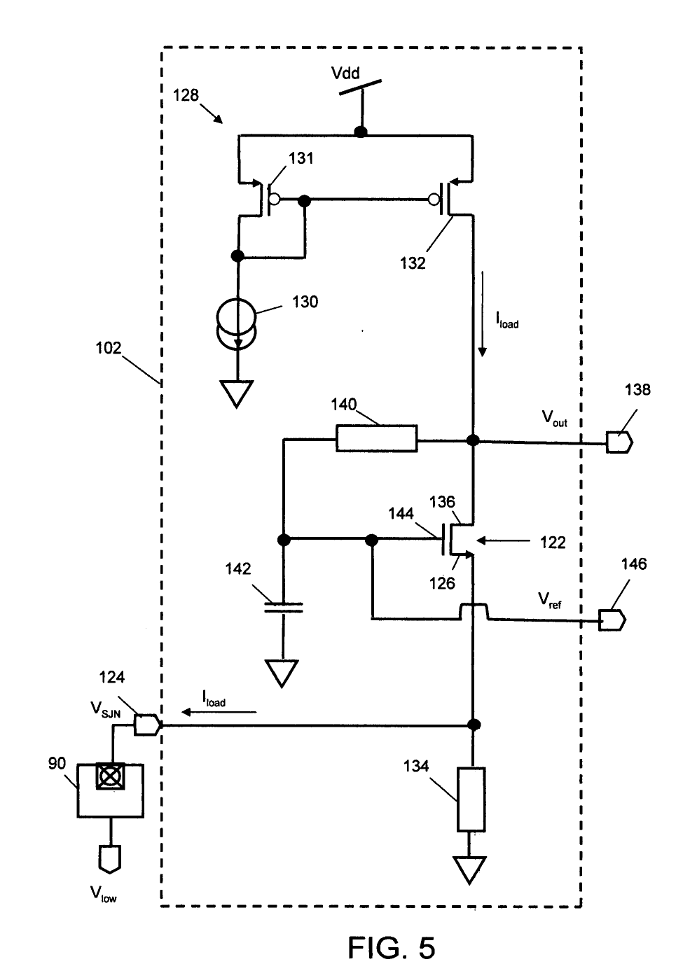

As shown in FIG. 5, the amplifying detector includes 102 a common-gate transistor 122 that provides the amplification. The load current I_{load} flows through the transistor into the solder-joint network 90. The common-gate transistor produces the analog output voltage Vₒᵤₜ at its drain terminal. Filter 114 is connected between the drain and gate terminals to bias the transistor and to produce the reference voltage V_{ref}. This approach eliminates the separate drain current that would be required to power an amplifier that was not connected between the current source 108 and solder-joint network, which lowers total current and power consumption.

The output pin of solder-joint network 90 is held at a low voltage on the die, suitably by pulling low the output buffer 50 of the I/O port 40 in FIG. 2. The low voltage of the solder-joint network is connected through wiring to input 124 of amplifying detector 102 to the source terminal 126 of transistor 122. A current-mirror 128 includes a constant-current sink 130 and a diode connected transistor 131 that biases a transistor 132 to draw the same amount of current as the constant-current sink to source a low value of constant load current I_{load}. The constant current flows through transistor 122 into a parallel circuit comprising a large-value shunt resistor 134 and the effective low-value resistance of solder-joint network 90. The shunt resistance is suitably included to bias transistor 122 and detect ‘open’ faults but is not required for ‘fault’ detection. When a resistance spike occurs in the solder-joint network, the constant current flowing through the resistance spike causes a voltage change at input 124. For example, a low value of constant current of 50 μA flowing through an effective resistance spike of 100Ω in solder-joint network 90 results in a very small change of about 5 mV at the source terminal 126 of transistor 122.

A small change in voltage, such as 5 mV for example, at input 124 is insufficient to change a turned-off or turned-on state in a comparator or logic gate, so a small change in voltage at input 124 needs to be amplified. Because the effective resistance of solder-joint network 90 is in the source circuit of the common-gate configuration of transistor 122, a voltage spike at input 122 is amplified: the small change in voltage is multiplied by the value of the effective load resistance of the drain terminal 136 of transistor 122 times the transfer conductance of transistor 122. The effective load resistance is largely determined by the parallel combination of resistor 140, the output resistance of transistor 132 and the output resistance of transistor 122. For AC, assuming the transistor output resistances are very large, in the Mega-Ohm range, the load resistance is slightly less than the resistance of resistor 140. For DC, capacitor 142 is effectively open so the large-signal output resistance is the parallel combination of the transistor output resistances. This small-signal gain and a large signal gain determined by the biasing of the common-gate transistor generate an analog output voltage Vₒᵤₜ at the transistor's drain terminal 136 that includes amplified steady-state, signal (network faults) and noise components at output 138. The amplified steady-state component is sensitive to the low voltage on the other side of the solder-joint network.

Resistor 140 and capacitor 142 define a filtered feedback circuit from the drain terminal 136 to the gate terminal 144 of transistor 122, which biases transistor 122 and which produces reference voltage V_{ref} at output 146. The filtered feedback causes V_{ref} to have a steady-state voltage equal to the steady-state voltage level of Vₒᵤₜ: a slow change in the steady-state low-voltage at input 124 becomes a slow change in the steady-state voltage of both Vₒᵤₜ and V_{ref}, which is an auto-adjusted voltage reference. The circuit values of resistor 140, the values of biasing circuit for current source 130 and the widths and lengths of transistors 122, 131 and 132 are designed to cause the detector to respond to voltage changes caused by resistance changes as low as 100Ω (or lower) and as high as an open using a constant-current lower than 200 μA, typically 100-150 μA. Although both noise and failure perturbations are amplified, noise suppression occurs because the output signal-to-noise ratio is increased from less than two to about three by the non-linear small signal gain.

Resistor 134 is a high-value shunt resistor of 10 s of 1000 s of Ohms. Should the effective resistance of solder-joint network 90 become very high, the current flowing through the now very high resistance in the source of transistor 122 causes the steady-state voltage value at output 146 to become high enough to be used to detect long-lasting, high-value resistances as effective open circuit conditions. Digital output buffer 106 in FIG. 4 is used to signal the detection of an effective opened solder-joint. The amplifying detector 102 has a low-value constant-current 138, high supply V_{dd} and low supply Vₛₛ shown as ground reference.

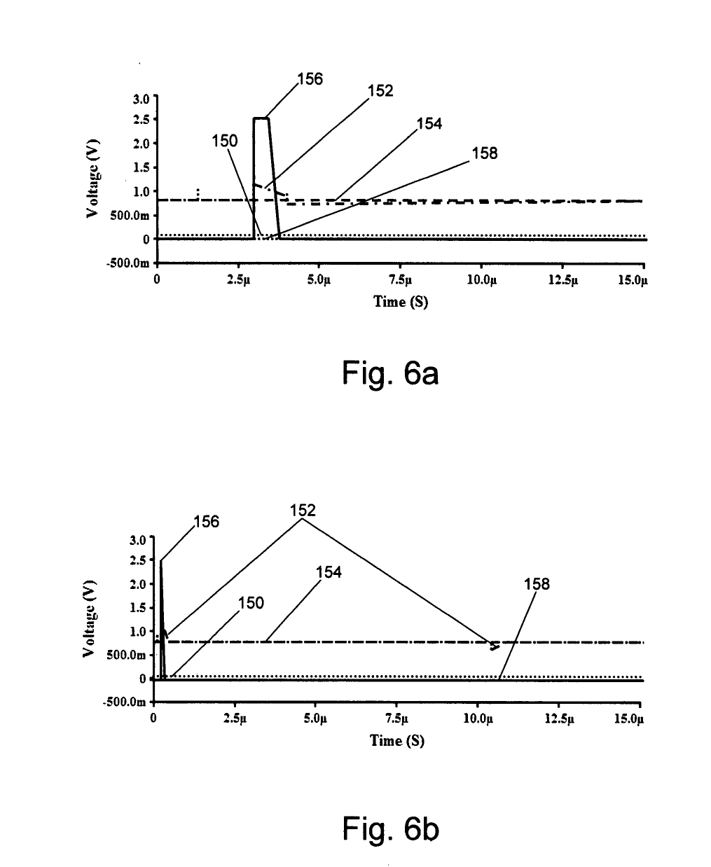

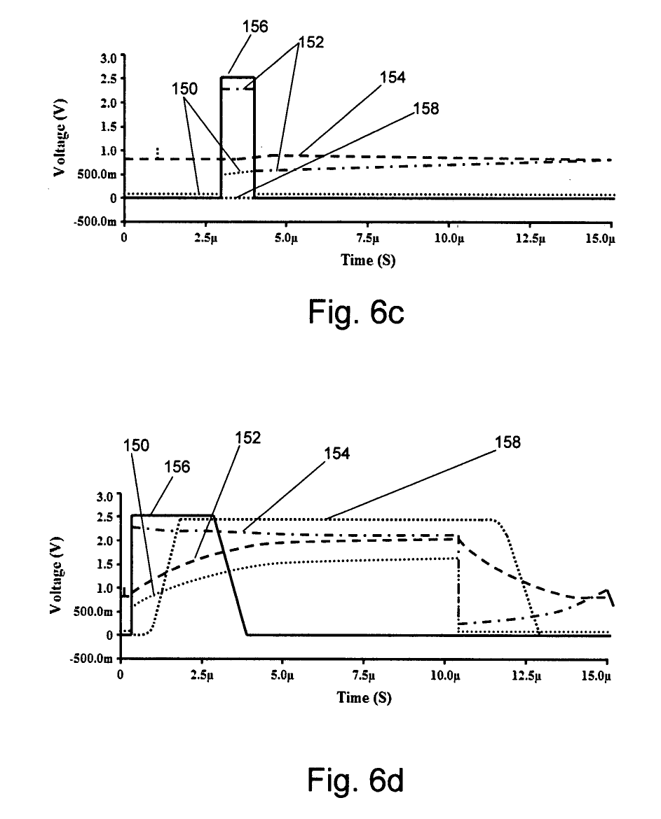

FIGS. 6a through 6d are plots of simulated solder-joint network 150, drain (Vₒᵤₜ) 152, gate (V_{ref}) 154, fault 156 and open 158 voltage signals for four different cases of network faults: short/small (1 μsec, 100 Ohm), long/small (100 μsec, 100 Ohm), short/large (1 μsec, open), long/large (100 μsec, open). As shown in FIG. 6a, a short/small fault produces an almost undetectable increase in network voltage 150, a few mv compared to the 1.25 V bias point. This fault is amplified and manifests as an increase in Vₒᵤₜ 152 at the drain terminal, which bleeds off with the time constant of the filter. V_{ref} actually increases but the increase is not noticeable for a short/short fault. The difference between Vₒᵤₜ and V_{ref} 154 switches the fault logic voltage 156 high. Voltage 156 will switch back low when the difference becomes too small. Because V_{ref} is essentially unchanged, the open logic voltage 158 remains low. As shown in FIGS. 6b and 6c, the voltage response and outputs are similar for long/small and short/large faults. As shown in FIG. 6d, a long/large fault produces a distinct spike in network voltage 150 which continues to increase (charging the RC filter) over the duration of the fault. The drain voltage Vₒᵤₜ 152 similarly spikes and switches the fault logic voltage 156 high. Because of the size and duration of the fault, the change in resistance begins to appear as a steady-state component. Gate voltage V_{ref} 154 charges up over the duration of the fault. When V_{ref} reaches ½ V_{dd} (1.5V in this example), the open logic voltage 158 switches high. The open logic voltage 158 remains high until V_{ref} bleeds back to the no-fault steady-state level. Although shifted from the onset of the fault, the duration of the ‘open’ logic signal approximates the duration of the ‘open’ fault.

As mentioned previously, the performance of the solder-joint failure detector can be improved and power consumption reduced with additional input stages in the comparator that provide signal conditioning. A ‘full circuit’ comparator 120 includes a differential amplifier 170 and a level shifter 172. The differential amplifier differentially amplifies the output voltage Vₒᵤₜ and reference voltage V_{ref} so that the amplified signal and amplified noise ride on a fixed steady-state voltage that is determined by the bias conditions of the amplifier and insensitive to the low voltage input at the solder-joint network. The output of this stage is a differential signal in which a positive signal V+ rides on the fixed steady-state voltage and a negative signal V− rides on the fixed steady-state voltage. The use of the differential amplifier establishes a reliable steady-state voltage or bias, which is insensitive to the low voltage on the network, into the differential comparator 116. This bias point is selected to provide a desired non-linear amplification of the signal voltage as compared to noise to improve SNR. Level-shift stage 172 level shifts one of the outputs, V+ or V−, of the differential amplifier stage by, for example, the designed for noise threshold to input V+(shift) and V− into the differential comparator. As a result, the differential comparator 116 cancels noise thereby further improving SNR. The advantage is that the load current can be made smaller and achieve the same or better performance. Alternately, the level-shift stage may be positioned in front of the differential amplifier although this is more difficult because of the amplitude of the signal and noise. Alternately, the differential amplifier 170 may be used without the level shifter.

As shown in FIG. 8, a typical differential amplifier 170 includes input transistors 180 and 182, which are connected to diode-connected, current-source load transistors 184 and 186 connected to V_{dd}. A low-value constant-current sink 188 connected to ground reference supplies current to the amplifier. Voltages Vₒᵤₜ and V_{ref} are applied to inputs 190 and 192, respectively. The small-signal portion (signal and noise) of Vₒᵤₜ is amplified and inverted to produce output signal V− and amplified to produce output signal V+ at outputs 194 and 196, respectively. These signals both ride on a fixed steady-state voltage determined by the bias conditions of the amplifier. The SNR ratio is increased from, for example, 3 to 4, and the steady-state voltage is increased, which makes the small signal component less sensitive to exact values of the steady-state component of the low voltage applied to the solder-joint network.

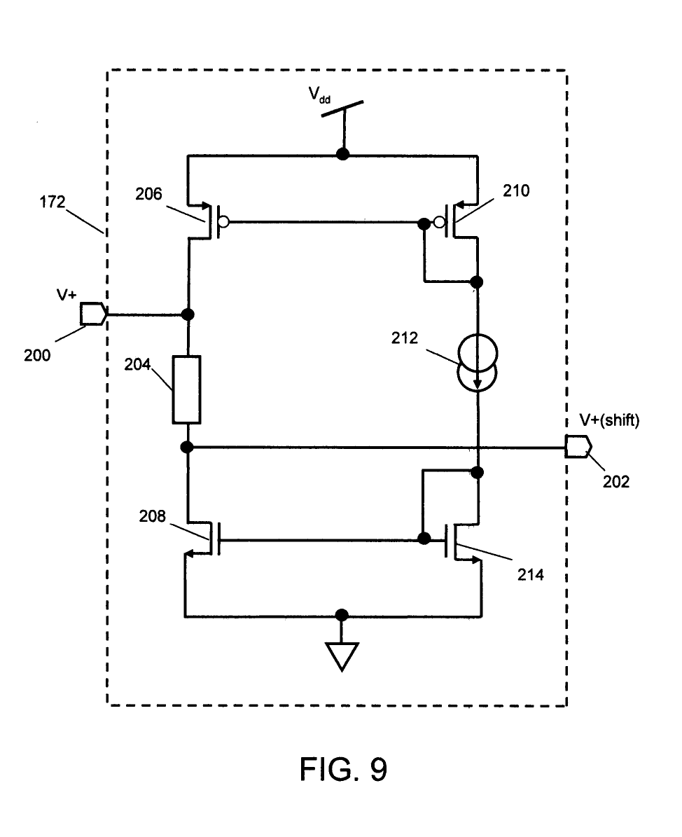

Referring to FIG. 9, the non-inverting signal V+ from differential amplifier 110 is input to level shifter 172 at input 200 and shifted to a lower steady-state voltage level V+(shift) at output 202. The shifted signal is a self-adjusted, floating voltage reference input to the differential comparator 116. The voltage level floats because it is always shifted by the same magnitude, regardless of the steady-state voltage level of Vₒᵤₜ. The level-shift causes the comparator 116 to suppress noise on the differential inputs V− and V+(shift). The magnitude of the voltage shift is determined by the value of resistor 204 and the magnitude of the current flowing through transistors 206 and 208. The magnitude of the current is set by the current mirror comprised of transistor 210, bias current 212, and transistor 214 connected between supply V_{dd} and ground. The magnitude of the voltage shift is suitably designed to be approximately equal to a designed for noise threshold (as amplified to this point in the circuit). For example, 2.5 mV of noise on the solder-joint network at input 124 may be amplified to 75 mV of noise into the differential comparator. Other circuit configurations can be used to provide a level shift.

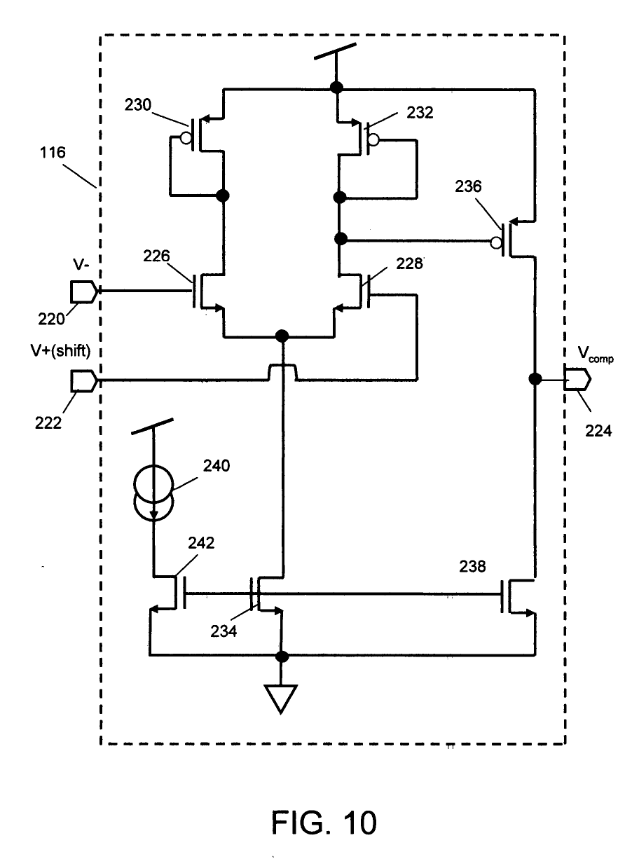

Referring to FIG. 10, differential comparator 116 is configured as a two stage operational trans-conductance amplifier (OTA) that compares voltage V− and V+(shift) at inputs 220 and 222, respectively and outputs a single-ended amplified analog signal V_{comp} at output 224. The first stage is a differential input, single-ended output amplifier comprised of input transistors 226 and 228, diode-connected, current-source load transistors 230 and 232, and current-sink transistor 234. The second stage is a common-source output amplifier comprised of transistor 236 and current-sink transistor 238. A constant current sink including constant-current source 240 and transistor 242 supplies current for both stages. The difference between V− and V+(shift) is amplified and output as a positive pulse voltage signal V_{comp}. The signal-to-noise ratio is, for example, increased from about four on inputs 220 and 222 to over sixteen on output 224.

Digital output buffers 106 and 118 are suitably comprised of two CMOS inverter sub-circuits. The first CMOS inverter converts the differential comparator from an output trans-conductance amplifier to an operational amplifier. The second CMOS inverter converts the analog output from the operational amplifier to digital outputs V_{F} or V_{O} with a signal to noise ratio of over 6000. A CMOS inverter includes a pair of transistors with inverted output connected in series between V_{dd} and ground reference.

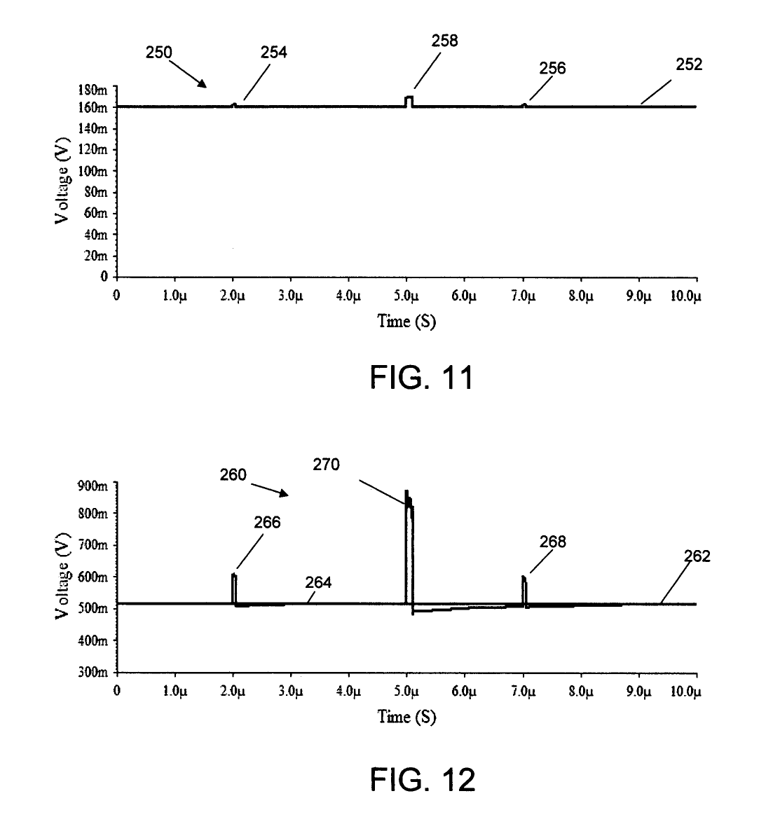

The analog voltage and logic signals generated at each stage of the solder-joint detector including a ‘full circuit’ comparator are illustrated in FIGS. 11-16 for a 200 Ohm, 0.1 microsecond (small/short) fault. The solder-joint network voltage V_{SJN} 250 has a steady-state voltage 252 of 160 mV, noise perturbations 254 and 256 of amplitude 2.5 mV, and a solder-joint failure perturbation 258 of amplitude 10 mV at time 5 microseconds for a load current of 50 μA. The steady-state voltage 252 is a function of the circuit applying the low-voltage to the other side of the network such as the write logic output buffer of an FPGA and the load current. This steady-state component may range from much higher than the 160 mV shown here down to a couple mV or ground potential without having a significant effect on the performance or power consumption of the detector.

As shown in FIG. 12, the amplifying detector amplifies and filters V_{SJN} 250 to produce amplified analog output voltage Vₒᵤₜ 260 and reference voltage V_{ref} 262. Vₒᵤₜ includes a steady-state component 264 of approximately 0.51 that is a function of the network low voltage and bias conditions of the detector, amplified noise perturbations 266 and 268 and an amplified signal 270. The signal has been amplified approximately 30 times from 10 mV to 334 mV. The noise has been amplified somewhat less, which increases the SNR to somewhat greater than 4. V_{ref} has only the steady-state component of Vₒᵤₜ.

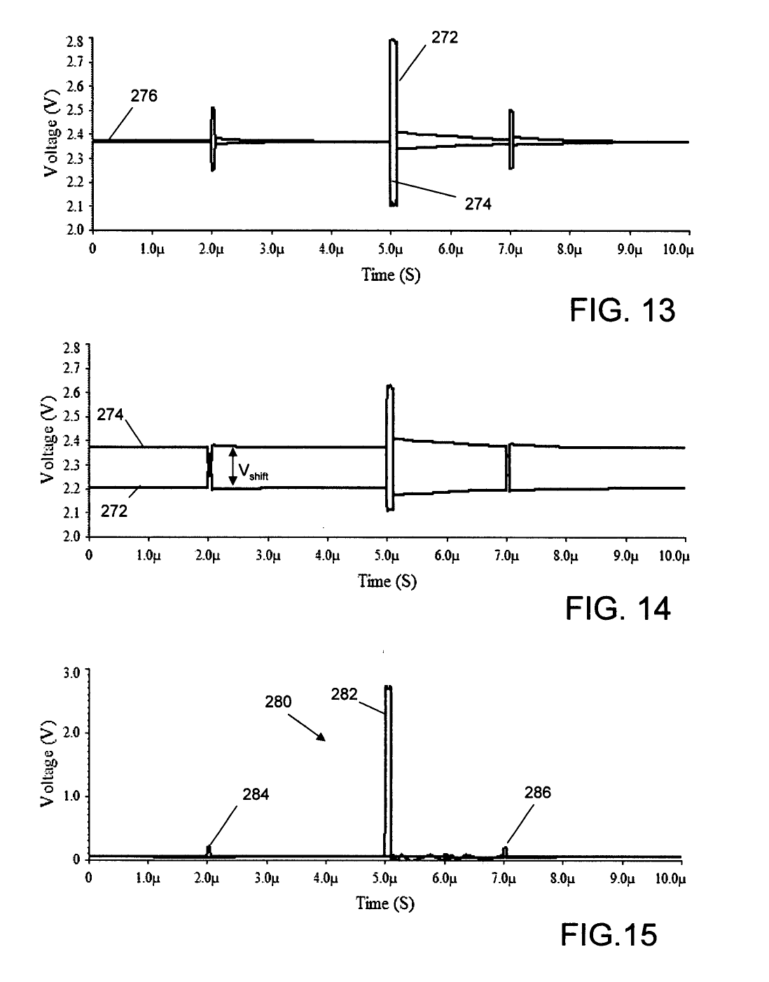

As shown in FIG. 13, the differential amplifier differentially amplifies Vₒᵤₜ and V_{ref} to produce a positive pulse voltage signal V+ 272 and a negative pulse voltage signal V− 274 that ride on a fixed bias voltage 276 that is insensitive to the network low voltage and preferably increases, approximately 2.37V compared to 0.5V into the differential amplifier. The positive pulse is about 405 mV and the negative pulse is about 245 mV. The differential amplifier increases SNR from about two to over three. As shown in FIG. 14, the level shifter has level shifted the positive pulse voltage signal 272 down by a fixed amount Vshift relative to the negative pulse voltage signal 274. The fixed amount is suitably equal to the designed for noise threshold, which in this example approximately matches the actual noise of about 160 mV.

As shown in FIG. 15, the differential comparator differentially compares and amplifies the positive and negative pulse signals to produce a single-ended analog voltage signal V_{comp} 280 including a signal component 282 (network failure) and noise components 284 and 286. Signal component 282 is approximately 2.8 V and the noise components are less about 0.28 V for a SNR of about ten. The SNR is improved by one the noise cancellation provided by the level shifter and two the fixed steady-state voltage input to the differential comparator provided by the differential amplifier. As discussed previously, the amplifier stages are preferably biased to operate in their non-linear region to provide more gain to the signal component and less gain to the noise. A key to improving the SNR reliably is to fix the steady-state voltage input to the stage.

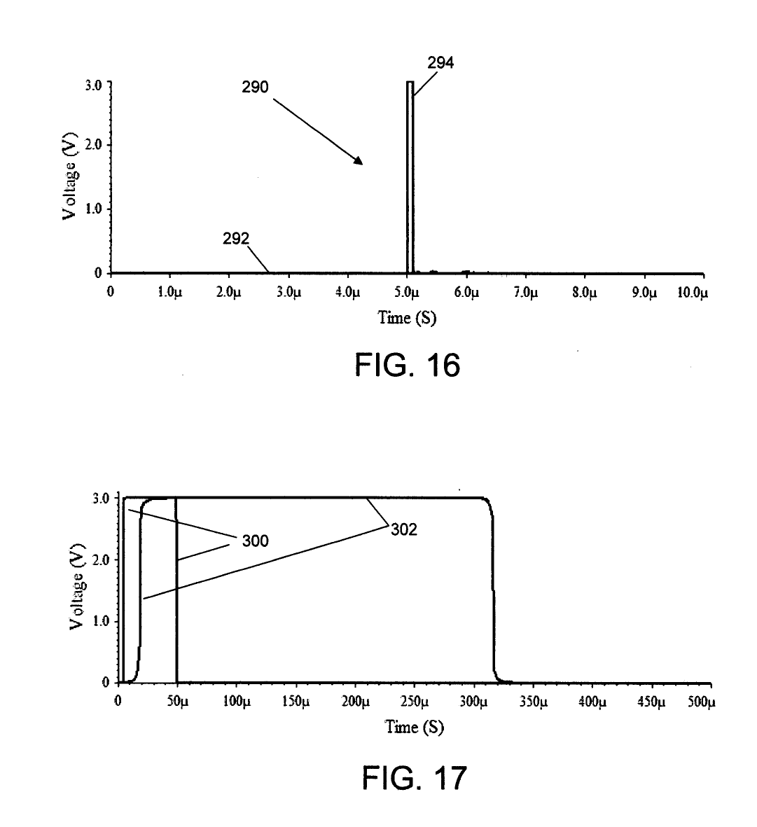

Referring to FIG. 16, the fault logic signal 290 generated by the output buffer remains in a low state 292 until the occurrence of the fault at which time it switches to a high state 294. The noise perturbations are suppressed to less than 1 mV in magnitude compared to the failure perturbations of magnitude 2.99 volts.

Referring to FIG. 17, a large/long (open, 310 microseconds) fault in the network occurs at 0 microseconds. The FAULT logic signal 300 switches high within a couple microseconds to indicate the occurrence of a fault and ends at time 50 microseconds. The OPEN logic signal 302 switches high at about 20 microseconds to indicate the occurrence of an open fault and does not begin to turn off until the open fault ends. The use of both FAULT and OPEN logic signals provides full-period coverage for both transient types of failures and long-lasting, high-value resistance failures. The detection circuitry could be modified or additional detection circuitry provided to detect specific occurrences of other faults such as short/small, short/large or long/small without departing from the scope of the invention.

While several illustrative embodiments of the invention have been shown and described, numerous variations and alternate embodiments will occur to those skilled in the art. Such variations and alternate embodiments are contemplated, and can be made without departing from the spirit and scope of the invention as defined in the appended claims.

We claim:

1. A fault detection circuit providing in-situ monitoring of the integrity of operational solder-joint networks, comprising:
a plurality of operational solder-joint networks, said plurality including at least one designated monitor solder-joint network held at a low voltage;
a current source that supplies a load current into the monitor solder-joint network to produce an analog solder-joint voltage;
an amplifier that provides small-signal gain to amplify the analog solder-joint voltage to produce an analog output voltage;
a filter that filters the output voltage to produce an analog reference voltage; and
a comparator that compares the analog output voltage to the analog reference voltage and switches a logic fault signal when a fault occurs in the monitored solder-joint network as an indicator of the integrity of the operational solder-joint networks.

2. The fault detection circuit of claim 1, wherein said comparator outputs the logic fault signal as an indicator of a failure in the monitor solder-joint network for increases in network resistance of at least as large as 100 Ohms.

3. The fault detection circuit of claim 2, wherein the load current is less than 200 microamps.

4. The fault detection circuit of claim 1, wherein said amplifier comprises a common-gate transistor having drain, gate and source terminals, said monitor solder-joint network connected to said source terminal, said load current flowing through said transistor into the monitor solder-joint network to produce the analog output voltage at the transistor's drain terminal, and said filter connected between said drain and gain terminals to bias the common-gate transistor and produce the reference voltage at the gate terminal.

5. The fault detection circuit of claim 1, wherein the comparator includes:
a differential comparator that differentially amplifies the analog output and reference voltages to produce a single-ended analog voltage; and
a first output buffer that is driven between logic levels 0 and 1 by the single-ended analog voltage to output the logic fault signal for the monitor solder-joint network.

6. The fault detection circuit of claim 5, said comparator further comprising:
a differential amplifier that differentially amplifies the analog output and reference voltages to produce positive and negative voltage signals that each ride on a fixed steady state voltage that is insensitive to the steady-state component of the low voltage applied to the solder-joint network, said positive and negative voltage signals on said fixed steady state voltage being input to the differential comparator.

7. The fault detection circuit of claim 6, wherein said fixed steady state voltage is shifted above the maximum reference voltage and set at a preferred bias point of the differential comparator to increase SNR.

8. The fault detection circuit of claim 6, further comprising:
a level-shifter that shifts either said positive or said negative voltage signal before the signal is input to the differential comparator to improve SNR of the single-ended analog voltage.

9. The fault detection circuit of claim 8, wherein the level-shifter shifts the voltage signal by a specific noise threshold for which the detection circuit is designed.

10. The fault detection circuit of claim 1, further comprising:
a second output buffer that is driven between logic levels 0 and 1 by the reference voltage to output an open fault signal when an open fault occurs in the monitored solder-joint network as an indicator of the integrity of the operational solder-joint networks.

11. The fault detection circuit of claim 10, wherein said open fault manifests as an in network resistance of at least 10 kilo-Ohms for at least 15 micro seconds.

12. The fault detection circuit of claim 1, further comprising a write logic output buffer that holds said monitor solder-joint network at the low voltage.

13. The fault detection circuit of claim 1, further comprising:
a digital electronic package including pins configured to form an array of external solder-joint connections and a die mounted inside the package, said die including electrical components configured using internal mechanical connections that are electrically coupled through operational pins to different ones of said external solder-joints to form said respective operational solder-joint networks and together constituting the operational digital electronic package, said die also including an internal mechanical connection electrically coupled through a monitor pin to one of said external solder-joints to form the monitored solder-joint network that is held at the low voltage on the die.

14. The fault detection circuit of claim 1, further comprising:
a digital electronic package configured to form an array of external solder-joints and a die mounted therein, said die including an array of operational buffer circuits connected through I/O contacts to respective external solder-joints that form said operational solder-joint networks, an operational buffer circuit being designated as a monitored circuit in which the monitored operational solder-joint network is held at a low voltage on the die by pulling the output of the buffer circuit low.

15. The fault detection circuit of claim 14, wherein said fault detection circuit and digital electronic package have a high supply voltage at ground potential and a low supply voltage at a negative potential, said package's monitored operational buffer circuits comprising an electrostatic discharge (ESD) protection circuit between the low supply voltage and the I/O contact so that with power off to the package the negative potential will cause a negative load current to flow through the solder-joint network out of the I/O contact allowing the fault detection circuit to detect faults with the digital electronic package powered off.

16. The fault detection circuit of claim 1, wherein said operational and monitor solder-joint networks provide connections on a printed wire board.

17. The fault detection circuit of claim 1, wherein said operational and monitor solder-joint networks provide connections between first and second printed wire boards.

18. A fault detection circuit providing in-situ monitoring of the integrity of operational solder-joint networks, comprising:
a digital electronic package configured to form an array of external solder-joints and a die mounted therein, said die including an array of operational buffer circuits connected through I/O contacts to respective external solder-joints that form said operational solder-joint networks, an operational buffer circuit being designated as a monitored circuit in which the monitored solder-joint network is held at a low voltage on the die by pulling the output of the buffer circuit low;
a common-gate transistor having gate, drain and source terminals, said monitor solder-joint network connected in series between said source terminal and said low voltage;
a current source that sources a load current that flows through the transistor into the monitor solder-joint network, said transistor amplifying the small signal voltage on the solder-joint network to produce an analog output voltage at its drain terminal;
a filtered feedback circuit between the transistor's drain and gate terminals that biases the transistor and produces a reference output voltage at the gate terminal; and
a comparator that compares the analog output voltage to the analog reference voltage and switches a logic fault signal when a fault occurs in the monitored solder-joint network as an indicator of the integrity of the operational solder-joint networks.

19. The fault detection circuit of claim 18, wherein the comparator includes:
a differential amplifier that differentially amplifies the analog output and reference voltages to produce positive and negative voltage signals that each ride on a fixed steady state voltage that is insensitive to the steady-state component of the low voltage applied to the solder-joint network;
a differential comparator that differentially amplifies the positive and negative voltage signals on the fixed steady state voltage to produce a single-ended analog voltage; and
an output buffer that is driven between logic levels 0 and 1 by the single-ended analog voltage to output the logic fault signal for the monitor solder-joint network.

20. The fault detection circuit of claim 19, further comprising:
a level-shifter that shifts either said positive or said negative voltage signal before the signals are input to the differential comparator to improve SNR of the single-ended analog voltage.

21. The fault detection circuit of claim 18, further comprising:
an output buffer that is driven between logic levels 0 and 1 by the reference voltage to output an open fault signal when an open fault occurs in the monitored solder-joint network as another indicator of the integrity of the operational solder-joint networks.

22. A method of monitoring in-situ the integrity of operational solder-joint networks, comprising:
providing a device having a plurality of operational solder-joint networks;
holding one side of a designated monitor solder-joint network at a low voltage;
sourcing current through the monitor solder-joint network to produce an analog solder-joint voltage;
amplifying the analog solder-joint voltage to produce an analog output voltage;
filtering the analog output voltage to produce a reference voltage; and
comparing the analog output and reference voltages to switch a logic fault signal when a fault occurs in the monitor solder-joint network as an indicator of the integrity of the operational solder-joint networks.

23. The method of claim 22, wherein the current is sourced through a common-gate transistor connected at its source terminal to the solder-joint network to produce the analog output voltage at the transistor's drain terminal, and to filter the analog output voltage to bias the common-gate transistor and produce the reference voltage at its gate terminal.

24. The method of claim 22, where the comparison step comprises:
differentially amplifying the analog output and reference voltages to produce positive and negative voltage signals that each ride on a fixed steady state voltage that is insensitive to the steady-state component of the low voltage applied to the solder-joint network;
differentially amplifying the positive and negative voltage signals on the fixed steady state voltage to produce a single-ended analog voltage; and
comparing the single-ended analog voltage to a threshold to drive the logic fault signal between logic levels 0 and 1.

25. The method of claim 24, further comprising:
level shifting either said positive or said negative voltage signal before the signals are differentially amplified to improve SNR of the single-ended analog voltage.

26. The method of claim 22, further comprising:
comparing the reference voltage to a threshold to switch a logic open signal when an open fault occurs in the monitor solder-joint network as another indicator of the integrity of the operational solder-joint networks.
